(19) United States
(12) Patent Application Publication
(10) Pub. No.: US 2021/0242000 A1
(43) Pub. Date: Aug. 5, 2021

(54) SPUTTERING TARGET FOR MAGNETIC RECORDING MEDIUM

(71) Applicants: TANAKA KIKINZOKU KOGYO K.K., Tokyo (JP); TOHOKU UNIVERSITY, Miyagi (JP)

(72) Inventors: Tomonari Kamada, Ibaraki (JP); Ryousuke Kushibiki, Ibaraki (JP); Kim Kong Tham, Ibaraki (JP); Shin Saito, Miyagi (JP)

(21) Appl. No.: 17/050,718

(22) PCT Filed: Jul. 25, 2019
(86) PCT No.: PCT/JP2019/030106

§ 371 Date: Oct. 26, 2020

(30) Foreign Application Priority Data
Jul. 31, 2018 (JP) 2018-143182

(51) Int. Cl. H01J 37/34; C23C 14/34

(52) U.S. Cl. CPC H01J 37/3426; C23C 14/3414

(57) ABSTRACT

For a further high capacity, provided is a sputtering target for a magnetic recording medium that can form a magnetic thin film having enhanced uniaxial magnetic anisotropy, reduced intergranular exchange coupling, and improved thermal stability and SNR (signal-to-noise ratio).

The sputtering target for a magnetic recording medium, comprises: a metal phase containing Pt and at least one or more selected from Cu and Ni, with the balance being Co and incidental impurities; and an oxide phase containing at least B₂O₃.

### TECHNICAL FIELD

The present invention relates to a sputtering target for a magnetic recording medium and specifically relates to a sputtering target comprising Co, Pt, and an oxide.

### BACKGROUND ART

In a magnetic disk of a hard disk drive, information signals are recorded in tiny bits of a magnetic recording medium. To further increase the recording density of the magnetic recording medium, it is necessary to shrink the size of a bit that retains a piece of recorded information while increasing a signal-to-noise ratio, which is an indicator of information quality. To increase a signal-to-noise ratio, it is essential to increase a signal or to reduce a noise.

As a magnetic recording medium for recording information signals, a magnetic thin film having a CoPt-based alloy-oxide granular structure is used today (see Non Patent Literature (NPL) 1, for example). This granular structure is formed from columnar CoPt-based alloy grains and the surrounding oxide grain boundaries.

To increase the recording density of such a magnetic recording medium, it is necessary to smoothen transition regions between recording bits to reduce noise. To smoothen transition regions between recording bits, it is required to reduce the size of the CoPt-based alloy grains contained in the magnetic thin film.

Meanwhile, when the size of magnetic grains is reduced, the intensity of a recorded signal that can be retained by one magnetic grain decreases. To reduce the size of magnetic grains while ensuring the intensity of recorded signals, it is necessary to reduce the distance between the centers of grains.

Moreover, when the size of the CoPt-based alloy grains in the magnetic recording medium is reduced further, so-called thermal fluctuations, in which recorded signals are lost due to impaired thermal stability by the superparamagnetic phenomenon, arise in some cases. Such thermal fluctuations are a major obstacle to higher recording density of a magnetic disk.

To overcome this obstacle, it is necessary to increase the magnetic energy in each CoPt-based alloy grain to exceed the thermal energy. The magnetic energy of each CoPt-based alloy grain is determined by the product v×Kᵤ of the volume v and the magnetocrystalline anisotropy constant Kᵤ of the CoPt-based alloy grain. Accordingly, to increase the magnetic energy of the CoPt-based alloy grain, it is essential to increase the magnetocrystalline anisotropy constant Kᵤ of the CoPt-based alloy grain (see NPL 2, for example).

Moreover, to grow columnar CoPt-based alloy grains with a large Kᵤ, it is required to realize the phase separation between the CoPt-based alloy grains and a grain boundary material. When intergranular interactions between the CoPt-based alloy grains increase due to insufficient phase separation between the CoPt-based alloy grains and the grain boundary material, the magnetic thin film having the CoPt-based alloy-oxide granular structure exhibits a low coercivity H_{c}. Consequently, thermal fluctuations tend to arise due to impaired thermal stability. Accordingly, it is also important to reduce intergranular interactions between the CoPt-based alloy grains.

It may be possible to reduce the size of magnetic grains as well as the distance between the centers of the magnetic grains by reducing the size of grains in a Ru underlayer (underlayer provided for orientation control of a magnetic recording medium).

However, it is difficult to reduce the size of grains in a Ru underlayer while maintaining the crystal orientation (see NPL 3, for example). For this reason, the grain size in a Ru underlayer of current magnetic recording media is about 7 nm to 8 nm with little change from the size when longitudinal magnetic recording media were switched to perpendicular magnetic recording media.

Meanwhile, reducing the size of magnetic grains has also been studied by improving a magnetic recording layer rather than a Ru underlayer. Specifically, in a CoPt-based alloy-oxide magnetic thin film, reducing the size of magnetic grains has been investigated by increasing the amount of the oxide added while reducing the volume ratio of the magnetic grains (see NPL 4, for example). By this technique, the size of the magnetic grains was successfully reduced. However, since the widths of grain boundaries increase as the amount of the oxide added increases in this technique, it is impossible to reduce the distance between the centers of the magnetic grains.

Further, in addition to a single oxide used for conventional CoPt-based alloy-oxide magnetic thin films, addition of a second oxide has been investigated (see NPL 5, for example). However, when a plurality of oxide materials are to be added, guidelines for selecting such materials have not yet been clarified and oxides used as grain boundary materials for CoPt-based alloy grains remain under study even today. Meanwhile, the present inventors found the effectiveness of incorporating a low-melting oxide and a high-melting oxide (specifically, incorporating B₂O₃ with a melting point as low as 450° C. and a high-melting oxide with a melting point higher than a CoPt alloy (about 1,450° C.)) and have proposed a sputtering target for magnetic recording medium comprising a CoPt-based alloy and oxides including B₂O₃ and a high-melting oxide (Patent Literature (PTL) 1).

### CITATION LIST

### Patent Literature

PTL 1: WO 2018/083951

### Non Patent Literature

NPL 1: T. Oikawa et al., IEEE Transactions on Magnetics, September 2002, Vol. 38, No. 5, pp. 1976-1978
NPL 2: S. N. Piramanayagam, Journal of Applied Physics, 2007, 102, 011301
NPL 3: S. N. Piramanayagam et al., Applied Physics Letters, 2006, 89, 162504
NPL 4: Y. Inaba et al., IEEE Transactions on Magnetics, July 2004, Vol. 40, No. 4, pp. 2486-2488
NPL 5: I. Tamai et al., IEEE Transactions on Magnetics, November 2008, Vol. 44, No. 11, pp. 3492-3495

### SUMMARY OF INVENTION

### Technical Problem

For a further high capacity, an object of the present invention is to provide a sputtering target for a magnetic recording medium that can form a magnetic thin film having enhanced uniaxial magnetic anisotropy, reduced intergranular exchange coupling, and improved thermal stability and SNR (signal-to-noise ratio).

### Solution to Problem

Different from the controlled oxide components employed in PTL 1, the present inventors found that enhanced uniaxial magnetic anisotropy and reduced intergranular exchange coupling can be realized by focusing on metal components, thereby completing the present invention.

According to the present invention, provided is a sputtering target for a magnetic recording medium, comprising: a metal phase containing Pt and at least one or more selected from Cu and Ni, with the balance being Co and incidental impurities; and an oxide phase containing at least B₂O₃.

It is preferable to contain, based on total metal phase components of the sputtering target for a magnetic recording medium, 1 mol % or more and 30 mol % or less of Pt and 0.5 mol % or more and 15 mol % or less of at least one or more selected from Cu and Ni; and to comprise, based on the sputtering target for a magnetic recording medium as a whole, 25 vol % or more and 40 vol % or less of the oxide phase.

Further, according to the present invention, provided is a sputtering target for a magnetic recording medium, comprising: a metal phase containing Pt, at least one or more selected from Cu and Ni, and at least one or more selected from Cr, Ru, and B, with the balance being Co and incidental impurities; and an oxide phase containing at least B₂O₃.

It is preferable to contain, based on total metal phase components of the sputtering target for a magnetic recording medium, 1 mol % or more and 30 mol % or less of Pt, 0.5 mol % or more and 15 mol % or less of at least one or more selected from Cu and Ni, and more than 0.5 mol % and 30 mol % or less of at least one or more selected from Cr, Ru, and B; and to comprise, based on the sputtering target for a magnetic recording medium as a whole, 25 vol % or more and 40 vol % or less of the oxide phase.

The oxide phase may further contain one or more oxides selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, LuO₃, and ZrO₂.

### Advantageous Effects of Invention

By using the sputtering target for a magnetic recording medium of the present invention, it is possible to produce a high-density magnetic recording medium with improved thermal stability and SNR due to enhanced uniaxial magnetic anisotropy and reduced intergranular exchange coupling.

### BRIEF DESCRIPTION OF DRAWINGS

FIG. 1 is SEM photograph (accelerating voltage of 15 keV) of a cross-section in the thickness direction of a sintered test piece in Example 1.

FIG. 2 is EDS maps of FIG. 1 (×3,000).

FIG. 3 is a magnetization curve for a granular medium of Example 1.

FIG. 4 is SEM photograph (accelerating voltage of 15 keV) of a cross-section in the thickness direction of a sintered test piece in Example 2.

FIG. 5 is EDS maps of FIG. 4 (×3,000).

FIG. 6 is XRD profiles in the direction perpendicular to a film surface for magnetic films of Examples 1 and 2 and Comparative Example 1.

FIG. 7 is TEM images of the magnetic films of Examples 1 and 2 and Comparative Example 1.

FIG. 8 is a graph showing measured results of Mₛ for the magnetic films of Examples 1 and 2 and Comparative Example 1.

FIG. 9 is a graph showing measured results of H_{c} for the magnetic films of Examples 1 and 2 and Comparative Example 1.

FIG. 10 is a graph showing measured results of Hₙ for the magnetic films of Examples 1 and 2 and Comparative Example 1.

FIG. 11 is a graph showing a for the magnetic films of Examples 1 and 2 and Comparative Example 1.

FIG. 12 is a graph showing measured results of Kᵤ^{Grain} for the magnetic films of Examples 1 and 2 and Comparative Example 1.

FIG. 13 is a graph showing measured results of Mₛ for magnetic films of Examples 2 and 3.

FIG. 14 is a graph showing measured results of He for the magnetic films of Examples 2 and 3.

FIG. 15 is a graph showing measured results of Hₙ for the magnetic films of Examples 2 and 3 FIG. 16 is a graph showing a for the magnetic films of Examples 2 and 3.

FIG. 17 is a graph showing measured results of Kᵤ^{Grain} for the magnetic films of Examples 2 and 3 and Comparative Example 1.

### DESCRIPTION OF EMBODIMENTS

Hereinafter, the present invention will be described in detail by reference to the accompanying drawings. However, the present invention is not limited thereto. Herein, a sputtering target for a magnetic recording medium is simply referred to as a sputtering target or a target in some cases.

### (1) First Embodiment

A sputtering target for magnetic recording medium according to the first embodiment of the present invention is characterized by comprising: a metal phase containing Pt and at least one or more selected from Cu and Ni, with the balance being Co and incidental impurities; and an oxide phase containing at least B₂O₃.

The target of the first embodiment preferably contains, in the metal phase, 1 mol % or more and 30 mol % or less of Pt and 0.5 mol % or more and 15 mol % or less of at least one or more selected from Cu and Ni, with the balance being Co and incidental impurities; and preferably comprises, based on the sputtering target for a magnetic recording medium as a whole, 25 vol % or more and 40 vol % or less of the oxide phase containing at least B₂O₃.

Co, Pt, and one or more selected from Cu and Ni are constituents of magnetic grains (tiny magnets) in the granular structure of a magnetic thin film to be formed by sputtering. Hereinafter, one or more selected from Cu and Ni are abbreviated to “X” in the present specification, and magnetic grains contained in a magnetic thin film of a magnetic recording medium formed by using the target of the first embodiment are also referred to as “CoPtX alloy grains.”

Co is a ferromagnetic metal element and plays a central role in the formation of magnetic grains (tiny magnets) in the granular structure of a magnetic thin film. From a viewpoint of increasing the magnetocrystalline anisotropy constant Kᵤ of CoPtX alloy grains (magnetic grains) in a magnetic thin film to be obtained by sputtering as well as maintaining the magnetism of the CoPtX alloy grains (magnetic grains) in the obtained magnetic thin film, the Co content ratio in the sputtering target according to the first embodiment is preferably set to 25 mol % or more and 98.5 mol % or less based on the total metal components.

Pt acts, by alloying with Co and X within a predetermined compositional range, to reduce the magnetic moment of the resulting alloy and plays a role in adjusting the intensity of the magnetism of magnetic grains. From a viewpoint of increasing the magnetocrystalline anisotropy constant Kᵤ of CoPtX alloy grains (magnetic grains) in a magnetic thin film to be obtained by sputtering as well as adjusting the magnetism of the CoPtX alloy grains (magnetic grains) in the obtained magnetic thin film, the Pt content ratio in the sputtering target according to the first embodiment is preferably set to 1 mol % or more and 30 mol % or less based on the total metal components.

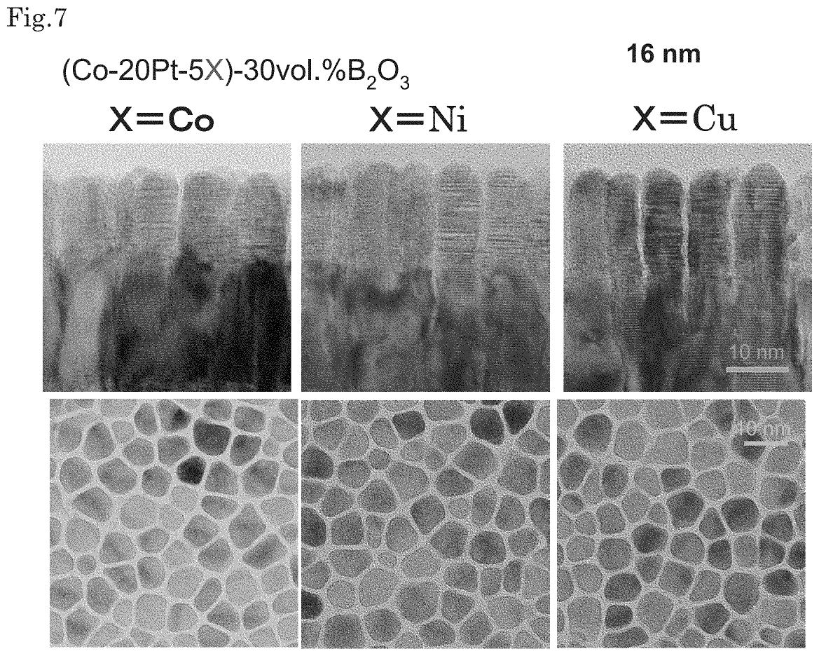

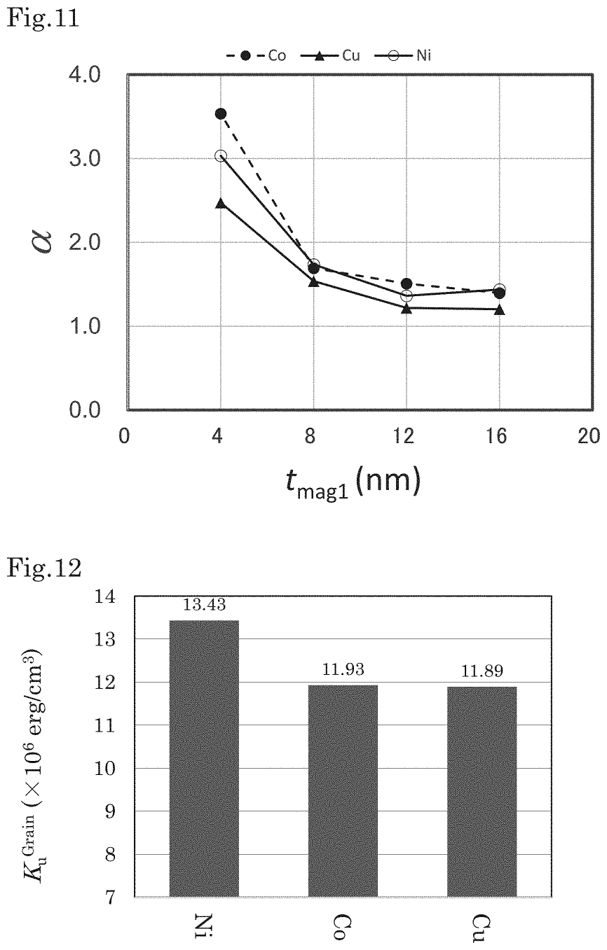

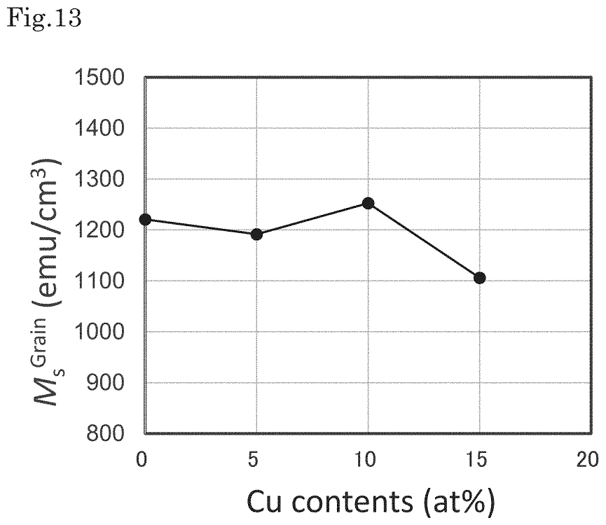

Cu acts to enhance the separation of CoPtX alloy grains (magnetic grains) by the oxide phase in a magnetic thin film and thus can reduce intergranular exchange coupling. Here, a magnetic thin film formed by sputtering using a CoPtCu—B₂O₃ target will be compared with a magnetic thin film formed by sputtering using a CoPt—B₂O₃ target. In the former, the B₂O₃ oxide phase exists deeper in the depth direction than the latter as partition walls between the neighboring CoPtCu alloy grains (FIG. 7: TEM images) and the magnetization curve has a smaller slope α at the intersection with the horizontal axis (applied magnetic field) than the latter (FIG. 11). Accordingly, it can be confirmed that the separation of magnetic grains is enhanced. Meanwhile, the former has the magnetocrystalline anisotropy constant Kᵤ^{Grain} per unit grain comparable to the latter (FIG. 12). Accordingly, it can be confirmed that the magnetic thin film exhibits satisfactory uniaxial magnetic anisotropy.

Ni acts to enhance uniaxial magnetic anisotropy of a magnetic thin film and thus can increase the magnetocrystalline anisotropy constant Kᵤ. Here, a magnetic thin film formed by sputtering using a CoPtNi—B₂O₃ target will be compared with a magnetic thin film formed by sputtering using a CoPt—B₂O₃ target. In the former, the B₂O₃ oxide phase exists deeper in the depth direction than the latter as partition walls between the neighboring CoPtNi alloy grains (FIG. 7: TEM images) and the magnetization curve has a slope α at the intersection with the horizontal axis (applied magnetic field) comparable to the latter (FIG. 11). Accordingly, it can be confirmed that the separation of magnetic grains is satisfactory. Meanwhile, the former has a higher magnetocrystalline anisotropy constant Kᵤ^{Grain} per unit grain than the latter (FIG. 12). Accordingly, it can be confirmed that the uniaxial magnetic anisotropy of the magnetic thin film is enhanced.

The content ratio of X in the sputtering target according to the first embodiment is preferably set to 0.5 mol % or more and 15 mol % or less based on the total metal phase components. Cu and Ni may be each alone or in combination contained as the metal phase components of the sputtering target. In particular, using Cu and Ni in combination is preferable since it is possible to reduce intergranular exchange coupling and enhance uniaxial magnetic anisotropy.

The oxide phase constitutes a nonmagnetic matrix that partitions magnetic grains (tiny magnets) in the granular structure of a magnetic thin film. The oxide phase of the sputtering target according to the first embodiment contains at least B₂O₃. As other oxides, one or more selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃. Lu₂O₃, and ZrO₂ may be contained.

B₂O₃ with a low melting point of 450° C. is slow to be deposited in the film forming process by sputtering. Accordingly, while CoPtX alloy grains grow into columnar grains, B₂O₃ in the liquid state exists between the columnar CoPtX alloy grains. For this reason, B₂O₃ is finally deposited as grain boundaries, which partition the CoPtX alloy grains that have grown into columnar grains, and constitutes a nonmagnetic matrix that partitions magnetic grains (tiny magnets) in the granular structure of a magnetic thin film. It is preferable to increase the oxide content in a magnetic thin film since magnetic grains are reliably and readily partitioned and isolated from each other. In this view, the oxide content in the sputtering target according to the first embodiment is preferably 25 vol % or more, more preferably 28 vol % or more, and further preferably 29 vol % or more. Meanwhile, when the oxide content in a magnetic thin film excessively increases, there is a risk that the oxide is mixed into CoPtX alloy grains (magnetic grains) and adversely affects the crystallinity of the CoPtX alloy grains (magnetic grains) to increase the proportion of structures other than hcp in the CoPtX alloy grains (magnetic grains). Moreover, a reduced number of magnetic grains per unit area in the magnetic thin film makes it difficult to increase the recording density. In this view, the oxide contents in the sputtering target according to the first embodiment is preferably 40 vol % or less, more preferably 35 vol % or less, and further preferably 31 vol % or less.

In the sputtering target according to the first embodiment, the total content ratio of metal phase components and the total content ratio of oxide phase components based on the entire sputtering target are determined by the intended component composition of a magnetic thin film and thus are not particularly limited. For example, the total content ratio of metal phase components may be set to 89.4 mol % or more and 96.4 mol % or less based on the entire sputtering target, and the total content ratio of oxide phase components may be set to 3.6 mol % or more and 11.6 mol % or less based on the entire sputtering target.

The microstructure of the sputtering target according to the first embodiment is not particularly limited but is preferably a microstructure in which the metal phase and the oxide phase are mutually and finely dispersed. Such a microstructure is less likely to cause trouble during sputtering, such as nodules or particles.

The sputtering target according to the first embodiment can be produced as follows, for example.

A molten CoPt alloy is prepared from metal components each weighed to satisfy a predetermined composition. The molten alloy was gas-atomized to yield CoPt alloy atomized powder. The prepared CoPt alloy atomized powder is classified into a predetermined particle size or less (106 μm or less, for example).

The prepared CoPt alloy atomized powder is added with X metal powder, B₂O₃ powder, and other oxide powders as necessary (for example, TiO₂ powder, SiO₂ powder, Ta₂O₅ powder, Cr₂O₃ powder, Al₂O₃ powder, ZrO₂ powder, Nb₂O₅ powder, MnO powder, Mn₃O₄ powder, CoO powder, Co₃O₄ powder, NiO powder, ZnO powder, Y₂O₃ powder, MoO₂ powder, WO₃ powder, La₂O₃ powder, CeO₂ powder, Nd₂O₃ powder, Sm₂O₃ powder, Eu₂O₃ powder, Gd₂O₃ powder, Yb₂O₃ powder, and Lu₂O₃ powder) and mixed/dispersed within a ball mill to yield a mixed powder for pressure sintering. Through mixing/dispersing of the CoPt alloy atomized powder, X metal powder, B₂O₃ powder, and other oxide powders as necessary in a ball mill, it is possible to prepare a mixed powder for pressure sintering in which the CoPt alloy atomized powder, X metal powder, B₂O₃ powder, and other oxide powders used as necessary are mutually and finely dispersed.

From a viewpoint of reliably partitioning and readily isolating magnetic grains from each other by B₂O₃ and other oxides as necessary in a magnetic thin film formed by using a sputtering target to be obtained, from a viewpoint of facilitating the formation of the hcp structure of CoPtX alloy grains (magnetic grains), and from a viewpoint of increasing the recording density, the total volume fraction of B₂O₃ powder and other oxide powders used as necessary is preferably 25 vol % or more and 40 vol % or less, more preferably 28 vol % or more and 35 vol % or less, and further preferably 29 vol % or more and 31 vol % or less based on the entire mixed powder for pressure sintering.

The prepared mixed powder for pressure sintering is formed to produce a sputtering target through pressure sintering by a vacuum hot press process. Since the mixed powder for pressure sintering has been mixed/dispersed in a ball mill, the CoPt alloy atomized powder. X metal powder, B₂O₃ powder, and other oxide powders used as necessary are mutually and finely dispersed. For this reason, when sputtering is performed using a sputtering target obtained by the present production method, trouble, such as generation of particles or nodules, is less likely to arise. Here, the pressure sintering process for the mixed powder for pressure sintering is not particularly limited, and a process other than the vacuum hot press process, such as the HIP process, may be employed.

To prepare a mixed powder for pressure sintering, each metal element powder may be used without being limited to the atomized powder. In this case, a mixed powder for pressure sintering can be prepared by mixing/dispersing each metal element powder, B₂O₃ powder, and other oxide powders as necessary in a ball mill.

### (2) Second Embodiment

A sputtering target for magnetic recording medium according to the second embodiment of the present invention is characterized by comprising: a metal phase containing Pt, at least one or more selected from Cu and Ni, and at least one or more selected from Cr, Ru, and B, with the balance being Co and incidental impurities; and an oxide phase containing at least B₂O₃.

The target of the second embodiment preferably comprises a metal phase containing 1 mol % or more and 30 mol % or less of Pt, more than 0.5 mol % and 30 mol % or less of at least one or more selected from Cr, Ru, and B, and 0.5 mol % or more and 15 mol % or less of at least one or more selected from Cu and Ni, with the balance being Co and incidental impurities; and preferably comprises, based on the sputtering target for a magnetic recording medium as a whole, 25 vol % or more and 40 vol % or less of one or more oxides including at least B₂O₃.

Co, Pt, one or more selected from Cu and Ni (hereinafter, also referred to as “X”), and one or more selected from Cr, Ru, and B (hereinafter, also referred to as “M”) are constituents of magnetic grains (tiny magnets) in the granular structure of a magnetic thin film to be formed by sputtering. Hereinafter, magnetic grains of the second embodiment are also referred to as “CoPtXM alloy grains” in the present specification.

Co is a ferromagnetic metal element and plays a central role in the formation of magnetic grains (tiny magnets) in the granular structure of a magnetic thin film. From a viewpoint of increasing the magnetocrystalline anisotropy constant Kᵤ of CoPtXM alloy grains (magnetic grains) in a magnetic thin film to be obtained by sputtering as well as maintaining the magnetism of the CoPtXM alloy grains (magnetic grains) in the obtained magnetic thin film, the Co content ratio in the sputtering target according to the second embodiment is preferably set to 25 mol % or more and 98 mol % or less based on the total metal components.

Pt acts, by alloying with Co, X, and M within a predetermined compositional range, to reduce the magnetic moment of the resulting alloy and plays a role in adjusting the intensity of the magnetism of magnetic grains. From a viewpoint of increasing the magnetocrystalline anisotropy constant Kᵤ of CoPtXM alloy grains (magnetic grains) in a magnetic thin film to be obtained by sputtering as well as adjusting the magnetism of the CoPtXM alloy grains (magnetic grains) in the obtained magnetic thin film, the Pt content ratio in the sputtering target according to the second embodiment is preferably set to 1 mol % or more and 30 mol % or less based on the total metal phase components.

At least one or more selected from Cr, Ru, and B act, by alloying with Co within a predetermined compositional range, to reduce the magnetic moment of Co and play a role in adjusting the intensity of the magnetism of magnetic grains. From a viewpoint of increasing the magnetocrystalline anisotropy constant Kᵤ of CoPtXM alloy grains (magnetic grains) in a magnetic thin film to be obtained by sputtering as well as maintaining the magnetism of the CoPtXM alloy grains in the obtained magnetic thin film, the content ratio of at least one or more selected from Cr, Ru, and B in the sputtering target according to the second embodiment is preferably set to more than 0.5 mol % and 30 mol % or less based on the total metal phase components. Cr, Ru, and B may be used alone or in combination and form the metal phase of the sputtering target together with Co and Pt.

Cu acts to enhance the separation of CoPtXM alloy grains (magnetic grains) by the oxide phase in a magnetic thin film and thus can reduce intergranular exchange coupling.

Ni acts to enhance uniaxial magnetic anisotropy of a magnetic thin film and thus can increase the magnetocrystalline anisotropy constant Kᵤ.

The content ratio of X in the sputtering target according to the second embodiment is preferably set to 0.5 mol % or more and 15 mol % or less based on the total metal phase components. Cu and Ni may be each alone or in combination contained as metal phase components of the sputtering target. In particular, using Cu and Ni in combination is preferable since it is possible to reduce intergranular exchange coupling and enhance uniaxial magnetic anisotropy.

The oxide phase constitutes a nonmagnetic matrix that partitions magnetic grains (tiny magnets) in the granular structure of a magnetic thin film. The oxide phase of the sputtering target according to the second embodiment contains at least B₂O₃. As other oxide components, one or more selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, Lu₂O₃, and ZrO₂ may be contained.

B₂O₃ with a low melting point of 450° C. is slow to be deposited in the film forming process by sputtering. Accordingly, while CoPtXM alloy grains grow into columnar grains, B₂O₃ in the liquid state exists between the columnar CoPtXM alloy grains. For this reason, B₂O₃ is finally deposited as grain boundaries, which partition CoPtXM alloy grains that have grown into columnar grains, and constitutes a nonmagnetic matrix that partitions magnetic grains (tiny magnets) in the granular structure of a magnetic thin film. It is preferable to increase the oxide content in a magnetic thin film since magnetic grains are reliably and readily partitioned and isolated from each other. In this view, the oxide content in the sputtering target according to the second embodiment is preferably 25 vol % or more, more preferably 28 vol % or more, and further preferably 29 vol % or more. Meanwhile, when the oxide content in the magnetic thin film excessively increases, there is a risk that the oxide is mixed into CoPtXM alloy grains (magnetic grains) and adversely affects the crystallinity of the CoPtXM alloy grains (magnetic grains) to increase the proportion of structures other than hcp in the CoPtXM alloy grains (magnetic grains). Moreover, a reduced number of magnetic grains per unit area in the magnetic thin film makes it difficult to increase the recording density. In this view, the content of the oxide phase in the sputtering target according to the second embodiment is preferably 40 vol % or less, more preferably 35 vol % or less, and further preferably 31 vol % or less.

In the sputtering target according to the second embodiment, the total content ratio of metal phase components and the total content ratio of oxide phase components based on the entire sputtering target are determined by the intended component composition of a magnetic thin film and thus are not particularly limited. For example, the total content ratio of metal phase components may be set to 88.2 mol % or more and 96.4 mol % or less based on the entire sputtering target, and the total content ratio of oxide phase components may be set to 3.6 mol % or more and 11.8 mol % or less based on the entire sputtering target.

The microstructure of the sputtering target according to the second embodiment is not particularly limited but is preferably a microstructure in which the metal phase and the oxide phase are mutually and finely dispersed. Such a microstructure is less likely to cause trouble during sputtering, such as nodules or particles.

The sputtering target according to the second embodiment can be produced as follows, for example.

A molten CoPtM alloy is prepared from Co, Pt, and one or more (M) selected from Cr, Ru, and B each weighed to satisfy a predetermined composition. The molten alloy was gas-atomized to yield CoPtM alloy atomized powder. The prepared CoPtM alloy atomized powder is classified into a predetermined particle size or less (106 μm or less, for example).

The prepared CoPtM alloy atomized powder is added with X metal powder, B₂O₃ powder, and other oxide powders as necessary (for example, TiO₂ powder, SiO₂ powder, Ta₂O₅ powder, Cr₂O₃ powder, Al₂O₃ powder, ZrO₂ powder, Nb₂O₅ powder, MnO powder, Mn₃O₄ powder, CoO powder, Co₃O₄ powder, NiO powder, ZnO powder, Y₂O₃ powder, MoO₂ powder, WO₃ powder, La₂O₃ powder, CeO₂ powder, Nd₂O₃ powder, Sm₂O₃ powder, Eu₂O₃ powder, Gd₂O₃ powder, Yb₂O₃ powder, and Lu₂O₃ powder) and mixed/dispersed in a ball mill to yield a mixed powder for pressure sintering. Through mixing/dispersing of the CoPtM alloy atomized powder, X metal powder, B₂O₃ powder, and other oxide powders as necessary in a ball mill, it is possible to prepare a mixed powder for pressure sintering in which the CoPtM alloy atomized powder, X metal powder, B₂O₃ powder, and other oxide powders used as necessary are mutually and finely dispersed.

From a viewpoint of reliably partitioning and readily isolating magnetic grains from each other by B₂O₃ and other oxides as necessary in a magnetic thin film formed by using a sputtering target to be obtained, from a viewpoint of facilitating the formation of the hcp structure of CoPtXM alloy grains (magnetic grains), and from a viewpoint of increasing the recording density, the total volume fraction of B₂O₃ powder and other oxide powders used as necessary is preferably 25 vol % or more and 40 vol % or less, more preferably 28 vol % or more and 35 vol % or less, and further preferably 29 vol % or more and 31 vol % or less based on the entire mixed powder for pressure sintering.

The prepared mixed powder for pressure sintering is formed to produce a sputtering target through pressure sintering by a vacuum hot press process, for example. Since the mixed powder for pressure sintering has been mixed/dispersed in a ball mill, the CoPtM alloy atomized powder, X metal powder, B₂O₃ powder, and other oxide powders used as necessary are mutually and finely dispersed. For this reason, when sputtering is performed by using a sputtering target obtained by the present production method, trouble, such as generation of particles or nodules, is less likely to arise. Here, the pressure sintering process for the mixed powder for pressure sintering is not particularly limited, and a process other than the vacuum hot press process, such as the HIP process, may be employed.

To prepare a mixed powder for pressure sintering, each metal element powder may be used without being limited to the atomized powder. In this case, a mixed powder for pressure sintering can be prepared by mixing/dispersing each metal element powder, B powder as necessary. B₂O₃ powder, and other oxide powders as necessary in a ball mill.

### EXAMPLES

Hereinafter, the present invention will be described further by means of Examples and Comparative Examples. In any of the Examples and the Comparative Examples, the total oxide content in a sputtering target was set to 30 vol %.

### Example 1

The composition of the entire target prepared as Example 1 is (75Co-20Pt-5Ni)-30 vol % B₂O₃ (atomic ratio for metal components), which is expressed by the molar ratio as 92.55(75Co-20Pt-5Ni)-7.45B₂O₃.

To produce the target according to Example 1, 50Co-50Pt alloy atomized powder and 100Co atomized powder were prepared first. Specifically, for the alloy atomized powder, each metal was weighed to satisfy the composition of 50 at % of Co and 50 at % of Pt. Both 50Co-50Pt alloy atomized powder and 100Co atomized powder were prepared by heating metal(s) to 1,500° C. or higher to form a molten alloy or a molten metal, followed by gas atomization.

The prepared 50Co-50Pt alloy atomized powder and 100Co atomized powder were classified through a 150 mesh sieve to obtain 50Co-50Pt alloy atomized powder and 100Co atomized powder each having a particle size of 106 μm or less.

To satisfy the composition of (75Co-20Pt-5Ni)-30 vol % B₂O₃, Ni powder and B₂O₃ powder were added to the classified 50Co-50Pt alloy atomized powder and 100Co atomized powder and mixed/dispersed in a ball mill to yield a mixed powder for pressure sintering.

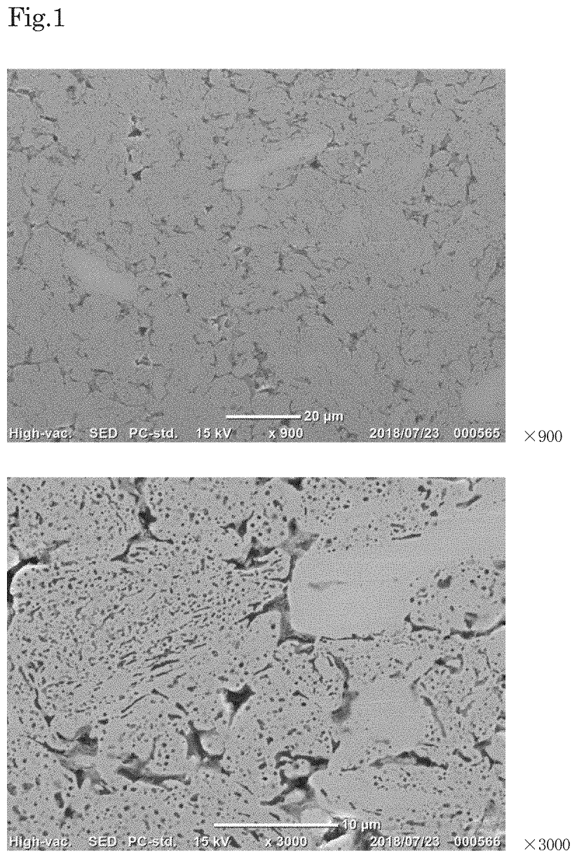

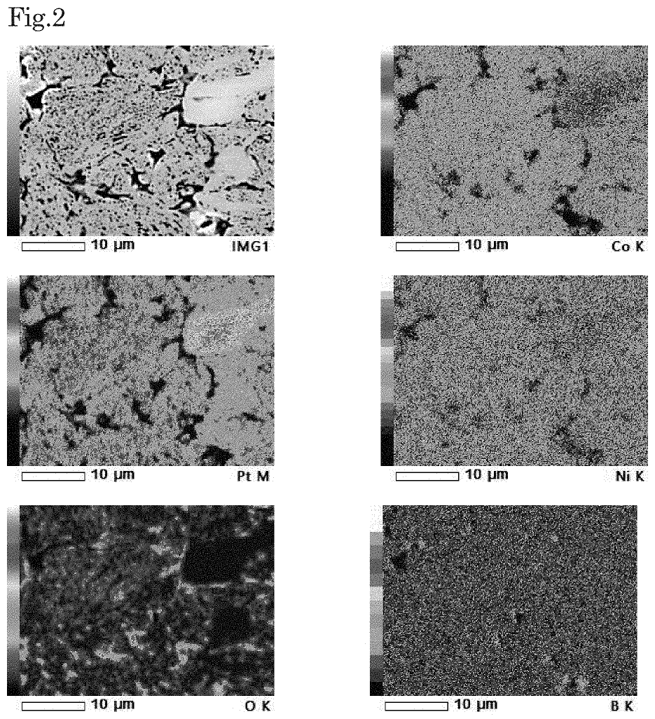

The obtained mixed powder for pressure sintering was hot-pressed at a sintering temperature of 710° C. and a sintering pressure of 24.5 MPa for a sintering time of 30 minutes in an atmosphere of a vacuum condition of 5×10⁻² Pa or less to yield a sintered test piece (030 mm). The prepared sintered test piece had a relative density of 100.4% and a calculated density of 9.04 g/cm³. The cross-section in the thickness direction of the obtained sintered test piece was mirror-polished and observed under a scanning electron microscope (SEM: JCM-6000Plus from JEOL Ltd.) at an accelerating voltage of 15 keV. The results are shown in FIG. 1. Moreover, compositional analysis of the cross-sectional structure was performed by an energy dispersive X-ray spectrometer (EDS) attached to the SEM. The results are shown in FIG. 2. From these results, the metal phase (75Co-20Pt-5Ni alloy phase) and the oxide phase (B₂O₃) were confirmed to be finely dispersed. The ICP analysis results of the obtained sintered test piece are shown in Table 3. Next, the prepared mixed powder for pressure sintering was hot-pressed at a sintering temperature of 920° C. and a sintering pressure of 24.5 MPa for a sintering time of 60 minutes in an atmosphere of a vacuum condition of 5×10⁻² Pa or less to produce a target (0153.0×1.0 mm+ø161.0×4.0 mm). The produced target had a relative density of 96.0%.

Sputtering was performed by using the prepared target in a DC sputtering apparatus (C 3010 from Canon Anelva Corporation) to form a magnetic thin film of (75Co-20Pt-5Ni)-30 vol % B₂O₃ on a glass substrate, thereby preparing a sample for magnetic characteristics measurement and a sample for structure observation. These samples have a layered structure of Ta (5 nm, 0.6 Pa)/Ni₉₀W₁₀(6 nm, 0.6 Pa)/Ru (10 nm, 0.6 Pa)/Ru (10 nm, 8 Pa)/CoPt alloy-oxide (8 nm, 4 Pa)/C (7 nm, 0.6 Pa) in this order from the side closer to the glass substrate. The numbers in the left side within the parentheses represent thickness, and the numbers in the right side represent pressure of Ar atmosphere during sputtering. The magnetic thin film formed by using the target prepared in Example 1 is CoPtNi alloy-oxide (B₂O₃) and is a magnetic thin film as a recording layer of a perpendicular magnetic recording medium. Here, the magnetic thin film was formed at room temperature without elevating the temperature of the substrate.

For measuring the magnetic characteristics of the obtained sample for magnetic characteristics measurement, a vibrating sample magnetometer (VSM: TM-VSM211483-HGC from Tamagawa Co., Ltd.), a torque magnetometer (TM-TR2050-HGC from Tamagawa Co., Ltd.), and a polar Kerr effect measurement apparatus (MOKE: BH-810CPM-CPC from Neoark Corporation) were used.

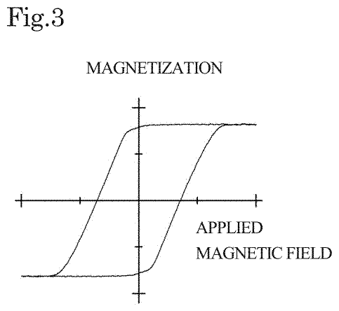

FIG. 3 shows an exemplary magnetization curve for a granular medium of the sample for magnetic characteristics measurement in Example 1. In FIG. 3, the horizontal axis represents the intensity of applied magnetic field and the vertical axis represents the intensity of magnetization per unit volume.

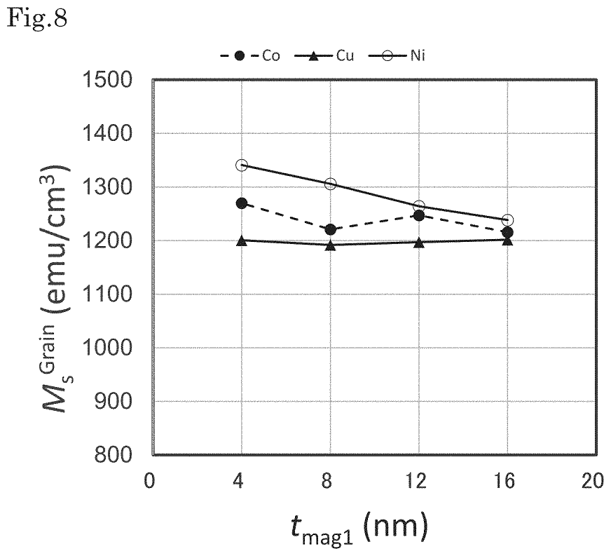

From the measured results of the magnetization curve for the granular medium of the sample for magnetic characteristics measurement, the saturation magnetization (Mₛ), coercivity (H), and slope (α) at the intersection with the horizontal axis were obtained. Moreover, the magnetocrystalline anisotropy constant (Kᵤ) was measured by using the torque magnetometer. These values, together with the results for other Examples and Comparative Examples, are shown in Table 1 and FIGS. 8 to 12.

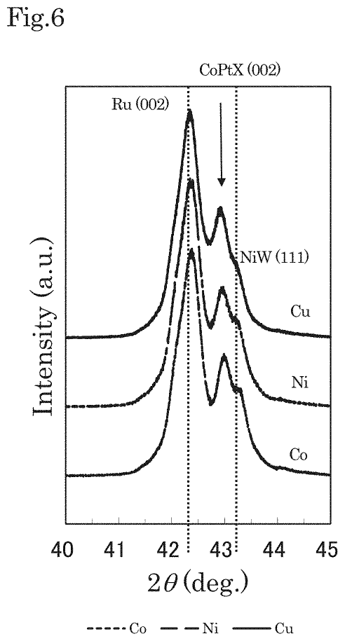

Further, for assessing the structure (assessing particle size and so forth of magnetic grains) of the obtained sample for structure observation, an X-ray diffractometer (XRD: SmartLab from Rigaku Corporation) and a transmission electron microscope (TEM: H-9500 from Hitachi High-Tech Corporation) were used. The XRD profile in the direction perpendicular to the film surface is shown in FIG. 6 and Table 2, and the TEM image is shown in FIG. 7.

### Example 2

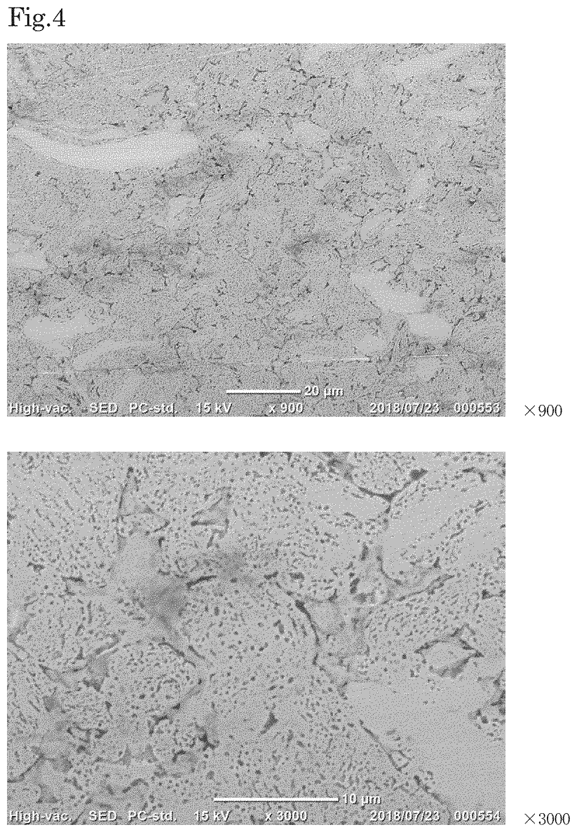

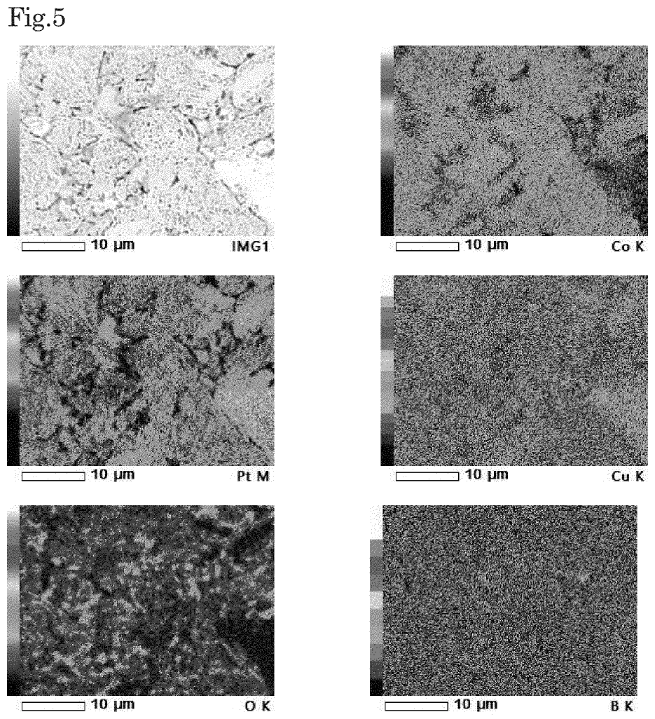

The composition of the entire target prepared in Example 2 is (75Co-20Pt-5Cu)-30 vol % B₂O₃ (atomic ratio for metal components), which is expressed by the molar ratio as 92.52(75Co-20Pt-5Cu)-7.48B₂O₃. A sample for magnetic characteristics measurement and a sample for structure observation were prepared and observed in the same manner as Example 1 except for changing the target composition from Example 1. The results are shown in FIGS. 4 and 5. The Cu powder used had an average particle size of 3 μm or less. A sintered test piece (ø30 mm) was prepared by hot pressing at a sintering temperature of 720° C. and a sintering pressure of 24.5 MPa for a sintering time of 30 minutes in an atmosphere of a vacuum condition of 5×10⁻² Pa or less. The prepared sintered test piece had a relative density of 99.8% and a calculated density of 9.03 g/cm³. The cross-section in the thickness direction of the obtained sintered test piece was observed under a metallurgical microscope, and the metal phase (75Co-20Pt-5Cu alloy phase) and the oxide phase (B₂O₃) were confirmed to be finely dispersed. The ICP analysis results of the obtained sintered test piece are shown in Table 3.

Next, a prepared mixed powder for pressure sintering was hot-pressed at a sintering temperature of 920° C. and a sintering pressure of 24.5 MPa for a sintering time of 60 minutes in an atmosphere of a vacuum condition of 5×10⁻² Pa or less to produce a target (ø153.0×1.0 mm+ø161.0×4.0 mm). The produced target had a relative density of 100.1%.

Later, magnetic characteristics assessment and structure observation for films were performed in the same manner as Example 1. The measured results of the magnetic characteristics, together with the target composition, are shown in Table 1 and FIGS. 8 to 12. Moreover, the XRD profile in the direction perpendicular to the film surface obtained by structure observation is shown in FIG. 6 and Table 2, and the TEM image is shown in FIG. 7.

### Comparative Example 1

A sintered test piece and a target were prepared as well as a magnetic thin film was formed and assessed in the same manner as Examples 1 and 2 except for changing the composition of the entire target to (80Co-20Pt)-30 vol % B₂O₃ (atomic ratio for metal components). The measured results of the magnetic characteristics, together with the target composition, are shown in Table 1 and FIGS. 8 to 12. The XRD profile in the direction perpendicular to the film surface obtained by structure observation is shown in FIG. 6, and the CoPt(002) peak position (2θ) and c-axis lattice constant read from the XRD profile are shown in Table 2. The TEM image is shown in FIG. 7, and the ICP analysis results of the obtained sintered test piece are shown in Table 3.

The symbols in Table 1 mean the following.

t_{Mag1}: thickness of magnetic layer in layered film
Mₛ^{Grain}: saturation magnetization solely for magnetic grains of magnetic layer in layered film
H_{c}: coercivity measured by Kerr effect
Hₙ: nucleation field measured by Kerr effect
α: slope at intersection with horizontal axis (applied magnetic field) of magnetization curve measured by Kerr effect
H_{c}−Hₙ: difference between coercivity and nucleation field measured by Kerr effect
Kᵤ^{Grain}: magnetocrystalline anisotropy constant solely for magnetic grains of magnetic layer in layered film

TABLE 1
Measured results of magnetic characteristics

| | t_{Mag, 1} | Mₛ^{Grain} | H_{c} | Hₙ | | H_{c} − Hₙ | Kᵤ^{Grain} |
|---|---|---|---|---|---|---|---|
| X | (nm) | (emu/cm³) | (kOe) | (kOe) | α | (kOe) | (*10⁶ erg/cm³) |
| Co | 16 | 1215.72 | 10.62 | 2.96 | 1.40 | 7.66 | |
| | 12 | 1247.06 | 9.49 | 2.22 | 1.51 | 7 27 | |
| | 8 | 1220.75 | 6.74 | 0.39 | 1.69 | 6.35 | 11.93 |
| | 4 | 1269.67 | 1.41 | −1.75 | 3.53 | 3.16 | |
| Cu | 16 | 1201.56 | 9.87 | 1.08 | 1.20 | 8.79 | |
| | 12 | 1197.03 | 8.38 | −0.26 | 1.22 | 8.64 | |
| | 8 | 1191.72 | 5.37 | −1.45 | 1.54 | 6.82 | 11.89 |
| | 4 | 1200.49 | 0.63 | −3.64 | 2.47 | 4.27 | |
| Ni | 16 | 1238.27 | 9.96 | 2.38 | 1.44 | 7.58 | |
| | 12 | 1264.09 | 8.91 | 0.75 | 1.36 | 8.16 | |
| | 8 | 1305.88 | 6.15 | −0.47 | 1.74 | 6.62 | 13.43 |
| | 4 | 1340.90 | 1.21 | −2.68 | 3.03 | 3.89 | |

TABLE 2
CoPt(002) peak position and C-axis lattice constant

| | CoPt(002) peak | C-axis lattice |
|---|---|---|
| X | position (°) | constant (Å) |
| Cu | 42.91 | 4.212 |
| Ni | 42.94 | 4.209 |
| Co | 42.97 | 4.206 |

TABLE 3
Component composition and ICP analysis results

| | | Measured values (weight ratio) | | | | | Metal component ratio | | | | |
|---|---|---|---|---|---|---|---|---|---|---|---|
| | | Co | Pt | Ni | Cu | B | (at % ratio) | | | | B₂O₃ |
| | Composition | concentration | concentration | concentration | concentration | concentration | Co | Pt | Ni | Cu | vol. % |
| Comp. Ex. 1 | (Co-20Pt)-30 | 52.03 | 41.97 | | | 1.89 | 80.4 | 19.6 | 0.0 | 0.0 | 29.8 |
| | vol. % B₂O₃ | | | | | | | | | | |
| Ex. 1 | (Co-20Pt-5Ni)-30 | 48.53 | 42.44 | 3.04 | | 1.90 | 75.4 | 19.9 | 4.7 | 0.0 | 30.0 |
| | vol. % B₂O₃ | | | | | | | | | | |
| Ex. 2 | (Co-20Pt-5Cu)-30 | 48.56 | 42.19 | | 3.20 | 1.94 | 75.6 | 19.8 | 0.0 | 4.6 | 30.5 |
| | vol. % B₂O₃ | | | | | | | | | | |

From FIG. 6 and Table 2, it is confirmed that the CoPt(002) peaks of Example 1 (Ni) and Example 2 (Cu) are shifted to lower angles relative to the peak of Comparative Example 1 (Co). Accordingly, at least part of Ni or Cu is considered to replace Co. However, the changes in c-axis lattice constant of the CoPt phase calculated from the peak positions are 0.01 Å or less. In addition, no structural change of the CoPt phase is observed. Meanwhile, no peak shift is observed for Ru and NiW.

In FIG. 7, it is observed that the gaps between the neighboring magnetic columns extend deeper in the depth direction in the magnetic thin film containing Ni or Cu than in the magnetic thin film (X=Co) containing neither Ni nor Cu. Accordingly, it is confirmed that the separation of magnetic grains is improved by using a target containing Ni or Cu.

FIG. 8 shows a slight increase in M: for Example 1 (Ni) and a slight decrease in Mₛ for Example 2 (Cu) relative to Comparative Example 1 (Co). However, these levels do not pose any problem in terms of maintaining the magnetism of CoPtX alloy grains (magnetic grains).

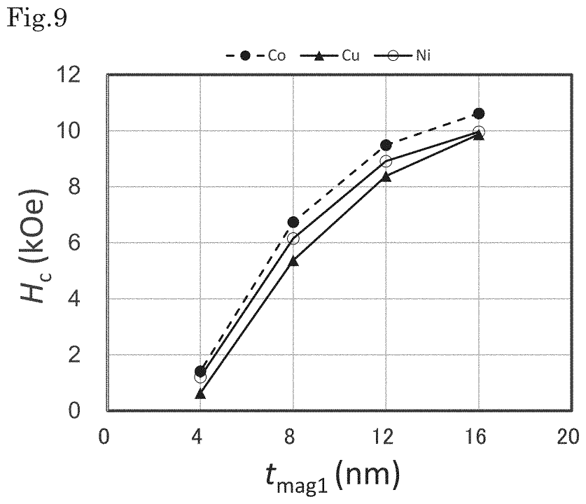

FIG. 9 reveals that the magnetic thin film containing Ni or Cu has He comparable to or slightly lower than the magnetic thin film (X=Co) containing neither Ni nor Cu. However, a further increase in He can be expected, for example, by optimizing the composition or by using Ni and Cu in combination.

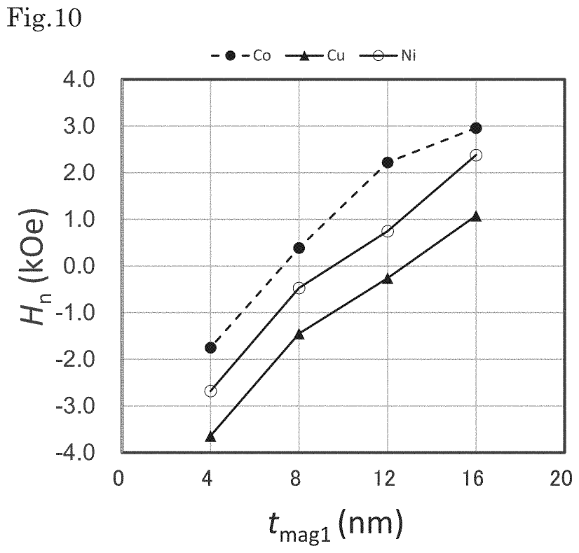

In FIG. 10, a lowering in He for Example 1 (Ni) and a further lowering in He for Example 2 (Cu) are observed relative to Comparative Example 1 (Co). This suggests improved separation of magnetic grains.

In FIG. 11, the Ni-containing magnetic thin film has a comparable to the Ni-free magnetic thin film (X=Co) and is thus confirmed to exhibit satisfactory separation of magnetic grains. In addition, the Cu-containing magnetic thin film has a smaller than the Cu-free magnetic thin film and is thus confirmed to exhibit improved separation of magnetic grains.

In FIG. 12, the Ni-containing magnetic thin film has K, higher than the Ni-free magnetic thin film (X=Co) and is thus confirmed to exhibit improved uniaxial magnetic anisotropy of magnetic grains by addition of Ni. Meanwhile, the Cu-containing magnetic thin film has Kᵤ comparable to the Cu-free magnetic thin film and is thus confirmed to maintain high uniaxial magnetic anisotropy.

### Example 3

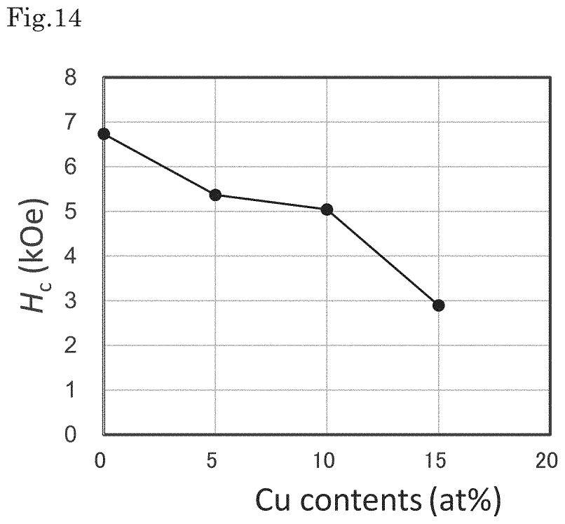

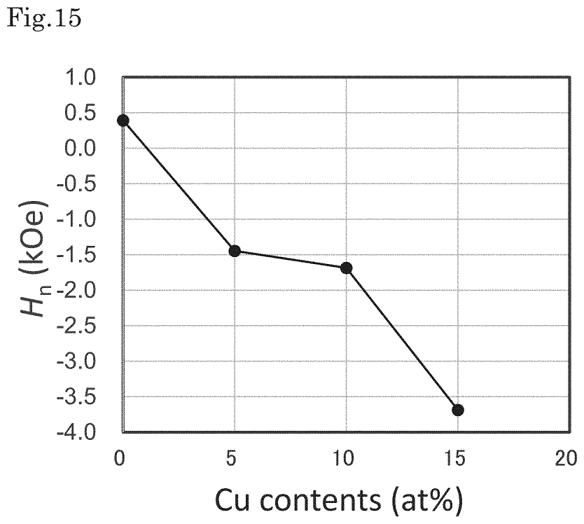

A target was prepared in the same manner as Examples 1 and 2 except for changing Cu content in the metal phase to 10 at % and 15 at % in the target of Example 2. A magnetic thin film was formed by using the target and assessed. The measured results of the magnetic characteristics are shown in Table 4 and FIGS. 13 to 17. In FIGS. 13 to 17, the results of Comparative Example 1 and the results of Example 2 are incorporated into 0 at % and 5 at % of Cu contents (at %), respectively.

TABLE 4
Measured results of magnetic characteristics

| | | | | | | Kᵤ^{Grain} |
|---|---|---|---|---|---|---|
| Cu contents | Mₛ^{Grain} | H_{c} | Hₙ | | H_{c} − Hₙ | (*10⁶ |
| (at %) | (emu/cm³) | (emu/cm³) | (kOe) | α | (kOe) | erg/cm³) |
| 10 | 1252.62 | 5.05 | −1.69 | 1.64 | 6.73 | 11.83 |
| 15 | 1106.06 | 2.90 | −3.69 | 1.48 | 6.58 | 8.99 |

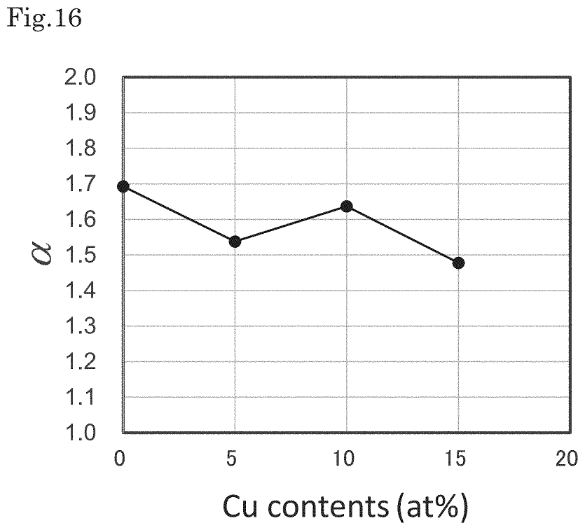

In FIG. 15, it is observed that the Cu-containing magnetic thin films have Hₙ smaller than the Cu-free magnetic thin film (Comparative Example 1: Cu contents=0 at %). In particular, Hₙ steeply decreases to −3.69 kOe at Cu content of 15 at %, suggesting remarkably improved separation of magnetic grains.

FIG. 16 shows a lowering in a for the Cu-containing magnetic thin films relative to the Cu-free magnetic thin film (Comparative Example 1: Cu contents=0 at %) and α of 1.48 at Cu content of 15 at %. Here, a is an indicator of magnetic separation, where α closer to 1 is better.

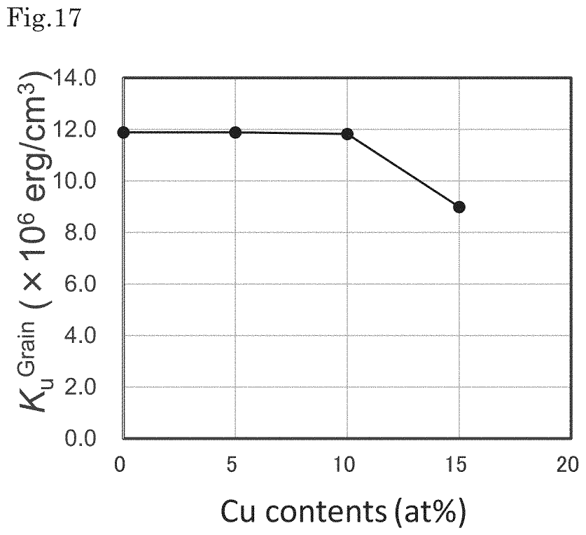

In FIG. 17, the Cu-containing magnetic thin films have Kᵤ comparable to the Cu-free magnetic thin film (Comparative Example 1: Cu contents=0 at %). Although a slight lowering is observed at Cu content of 15 at %, the magnetic thin film maintains Kᵤ of about 9×10⁶ erg/cm³ and is thus considered to exhibit satisfactory uniaxial magnetic anisotropy.

1. A sputtering target for a magnetic recording medium, comprising: a metal phase containing Pt and at least one or more selected from Cu and Ni, with the balance being Co and incidental impurities; and an oxide phase containing at least B₂O₃.

2. The sputtering target for a magnetic recording medium according to claim 1,
containing, based on total metal phase components of the sputtering target for a magnetic recording medium, 1 mol % or more and 30 mol % or less of Pt and 0.5 mol % or more and 15 mol % or less of at least one or more selected from Cu and Ni; and
comprising, based on the sputtering target for a magnetic recording medium as a whole, 25 vol % or more and 40 vol % or less of the oxide phase.

3. A sputtering target for a magnetic recording medium, comprising: a metal phase containing Pt, at least one or more selected from Cu and Ni, and at least one or more selected from Cr, Ru, and B, with the balance being Co and incidental impurities; and an oxide phase containing at least B₂O₃.

4. The sputtering target for a magnetic recording medium according to claim 3,
containing, based on total metal phase components of the sputtering target for a magnetic recording medium, 1 mol % or more and 30 mol % or less of Pt, 0.5 mol % or more and 15 mol % or less of at least one or more selected from Cu and Ni, and more than 0.5 mol % and 30 mol % or less of at least one or more selected from Cr, Ru, and B; and
comprising, based on the sputtering target for a magnetic recording medium as a whole, 25 vol % or more and 40 vol % or less of the oxide phase.

5. The sputtering target for a magnetic recording medium according to claim 1, wherein the oxide phase further contains one or more oxides selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, Lu₂O₃, and ZrO₂.

6. The sputtering target for a magnetic recording medium according to claim 2, wherein the oxide phase further contains one or more oxides selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, Lu₂O₃, and ZrO₂.

7. The sputtering target for a magnetic recording medium according to claim 3, wherein the oxide phase further contains one or more oxides selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, Lu₂O₃, and ZrO₂.

8. The sputtering target for a magnetic recording medium according to claim 4, wherein the oxide phase further contains one or more oxides selected from TiO₂, SiO₂, Ta₂O₅, Cr₂O₃, Al₂O₃, Nb₂O₅, MnO, Mn₃O₄, CoO, Co₃O₄, NiO, ZnO, Y₂O₃, MoO₂, WO₃, La₂O₃, CeO₂, Nd₂O₃, Sm₂O₃, Eu₂O₃, Gd₂O₃, Yb₂O₃, Lu₂O₃, and ZrO₂.
